(19) United States
(12) Patent Application Publication
(10) Pub. No.: US 2025/0107283 A1
(43) Pub. Date: Mar. 27, 2025

(54) LIGHT EMITTING ELEMENT

(71) Applicant: TOYODA GOSEI CO., LTD., Kiyosu-shi (JP)

(72) Inventors: Koji OKUNO, Kiyosu-shi (JP); Masaki OYA, Kiyosu-shi (JP); Yoshiki SAITO, Kiyosu-shi (JP)

(21) Appl. No.: 18/887,335

(22) Filed: Sep. 17, 2024

(30) Foreign Application Priority Data
Sep. 25, 2023 (JP) 2023-161494

(51) Int. Cl. H01L 33/32; H01L 33/00; H01L 33/06; H01L 33/14

(52) U.S. Cl. CPC H10H 20/825; H10H 20/81; H10H 20/812; H10H 20/816

(57) ABSTRACT

A light emitting element emits an ultraviolet ray, and includes: an n-type layer containing an n-type group III nitride semiconductor containing Al; an active layer located over the n-type layer, containing a group III nitride semiconductor containing Al, and having a quantum well structure including a well layer and a barrier layer; and a p-type layer located over the active layer and containing a p-type group III nitride semiconductor containing Al, and the barrier layer includes a first barrier layer non-doped or doped with an n-type impurity, and a second barrier layer located over the first barrier layer, being in contact with a surface of the well layer at a side of the n-type layer, and doped with an n-type impurity at a concentration higher than a concentration of the n-type impurity doped in the first barrier layer.

### CROSS-REFERENCE TO RELATED APPLICATION

This application is based on and claims priority under 35 USC 119 from Japanese Patent Application No. 2023-161494 filed on Sep. 25, 2023.

### TECHNICAL FIELD

The present invention relates to a light emitting element.

### BACKGROUND ART

A wavelength of an ultraviolet ray from a solid-state light emitting element using a group III nitride semiconductor corresponds to a wavelength band in a range of about 210 nm to 400 nm. In particular, it is known that UVC (wavelength: 100 nm to 280 nm) can efficiently sterilize and eliminate bacteria, and there is an increasing demand for a group III nitride semiconductor LED that emits an ultraviolet ray having an emission wavelength corresponding to that of the UVC. The ultraviolet LED has a structure in which an AlN layer is formed on a sapphire substrate and an n-type layer, an active layer, and a p-type layer made of AlGaN are stacked on the AlN layer.

In an LED using a group III nitride semiconductor, a piezoelectric field is generated due to a strain caused by a lattice mismatch between a well layer and a barrier layer of an active layer, and light emission efficiency decreases due to a quantum confined Stark effect (QCSE). In the ultraviolet LED, since an Al composition in AlGaN is high, the decrease in light emission efficiency due to the QCSE is more pronounced.

Known methods for preventing the decrease in light emission efficiency due to the QCSE include thinning the well layer and doping the barrier layer with Si. JP2021-34732A discloses that by doping a barrier layer with Si, a slope of a well layer band (an energy band in a direction perpendicular to a main surface of a substrate) is made closer to flat, and a light output of a deep ultraviolet LED is increased.

### SUMMARY OF INVENTION

On the active layer, a Mg-doped p-type layer such as an electron blocking layer is formed. In the method in JP2021-34732A, since the barrier layer is doped with Si, a distance between the n-type and the p-type is small, which causes deterioration in various properties when a reverse bias is applied. For example, an increase in leakage current, a decrease in breakdown voltage, deterioration in ESD properties, deterioration in reliability, and the like may occur.

The present invention has been made in view of such a background, and an object thereof is to provide a light emitting element having reduced deterioration in properties when a reverse bias is applied.

An aspect of the present invention is a light emitting element that emits an ultraviolet ray, the light emitting element including:
an n-type layer containing an n-type group III nitride semiconductor containing Al;
an active layer located over the n-type layer, containing a group III nitride semiconductor containing Al, and having a quantum well structure including a well layer and a barrier layer; and
a p-type layer located over the active layer and containing a p-type group III nitride semiconductor containing Al, wherein
the barrier layer includes
   a first barrier layer non-doped or doped with an n-type impurity, and
   a second barrier layer located over the first barrier layer, being in contact with a surface of the well layer at a side of the n-type layer, and doped with an n-type impurity at a concentration higher than a concentration of the n-type impurity doped in the first barrier layer.

In the above aspect, a structure including, as the barrier layer, the first barrier layer non-doped or doped with an n-type impurity and the second barrier layer located on the first barrier layer, in contact with the well layer, and doped with an n-type impurity at a concentration higher than that in the first barrier layer is obtained. Therefore, it is possible to improve a light emitting recombination probability and reduce the deterioration in properties when a reverse bias is applied.

### BRIEF DESCRIPTION OF DRAWINGS

FIG. 1 is a cross-sectional view showing a configuration of a light emitting element according to a first embodiment, which shows a cross section in a direction perpendicular to a main surface of a substrate.

FIG. 2 is a cross-sectional view showing a configuration of an active layer, which shows a cross section in the direction perpendicular to the main surface of the substrate.

FIG. 3 is a diagram showing a band diagram and a distribution of carrier concentration in a thickness direction of a light emitting element when 6 V is applied.

FIG. 4 is a diagram showing a band diagram and a distribution of carrier concentration in a thickness direction of a light emitting element when 6 V is applied.

FIG. 5 is a diagram showing a band diagram and a distribution of carrier concentration in a thickness direction of a light emitting element when 6 V is applied.

### DETAILED DESCRIPTION OF THE INVENTION

A light emitting element is a light emitting element that emits an ultraviolet ray, and includes: an n-type layer made of an n-type group III nitride semiconductor containing Al; an active layer located on the n-type layer, made of a group III nitride semiconductor containing Al, and having a quantum well structure including a well layer and a barrier layer; and a p-type layer located on the active layer and made of a p-type group III nitride semiconductor containing Al, and the barrier layer includes a first barrier layer non-doped or doped with an n-type impurity, and a second barrier layer located on the first barrier layer, in contact with a surface of the well layer facing the n-type layer, and doped with an n-type impurity at a concentration higher than a concentration in the first barrier layer.

In the above light emitting element, an uppermost barrier layer, which is a layer closest to the p-type layer among the barrier layers, may be a non-doped group III nitride semiconductor. Deterioration in properties when a reverse bias is applied can be further reduced.

In the above light emitting element, the first barrier layer may be non-doped, and the second barrier layer may have a Si concentration of 1×10¹⁸ cm⁻³ to 2×10¹⁹ cm⁻³. A light emitting recombination probability can be further improved, and the deterioration in properties when a reverse bias is applied can be further reduced.

In the above light emitting element, the first barrier layer may have a thickness of 2 nm to 20 nm, and the second barrier layer may have a thickness of 2 nm to 20 nm. The light emitting recombination probability can be further improved, and the deterioration in properties when a reverse bias is applied can be further reduced.

The above light emitting element may further include a hole blocking layer located between the n-type layer and the active layer, in contact with the active layer, and made of AlGaN or AIN having an Al composition higher than that in the barrier layer. A band of the entire active layer can be flattened, and efficiency of injecting holes into the active layer can be improved.

The above light emitting element may further include a superlattice layer located between the n-type layer and the hole blocking layer, in contact with the hole blocking layer, and formed by alternately stacking group III nitride semiconductors having different Al compositions.

In the above light emitting element, the active layer has an MQW structure.

### First Embodiment

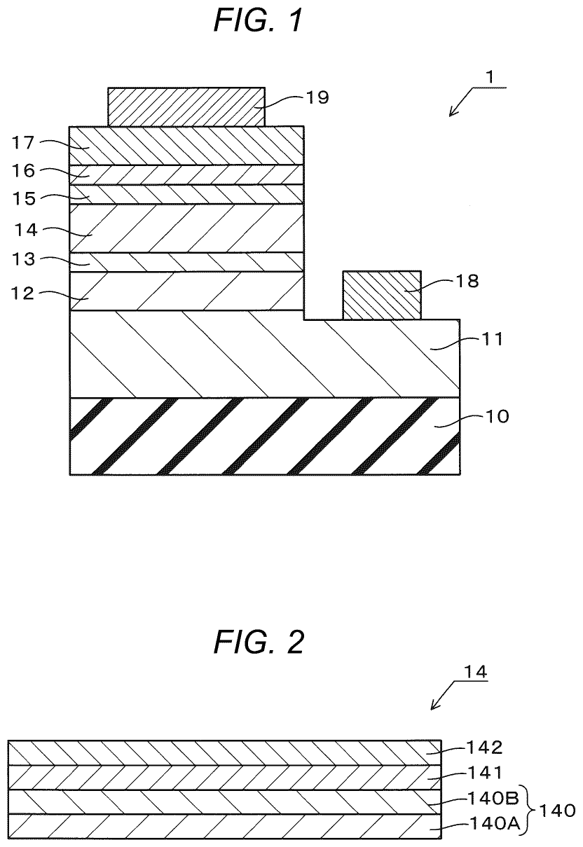

FIG. 1 is a diagram showing a configuration of a light emitting element 1 according to a first embodiment, which shows a cross section in a direction perpendicular to a main surface of a substrate. As shown in FIG. 1, the light emitting element 1 according to the first embodiment includes a substrate 10, an n-type layer 11, a superlattice layer 12, a hole blocking layer 13, an active layer 14, an electron blocking layer 15, a composition gradient layer 16, a p-type contact layer 17, an n-side electrode 18, and a p-side electrode 19.

### 1. Each Configuration of Light Emitting Element

A configuration of each layer of the light emitting element 1 according to the first embodiment will be described in detail.

The substrate 10 is a substrate made of sapphire and having a c plane as a main surface. A plane orientation of the main surface of the sapphire may be an a plane. The plane orientation may have an off angle of 0.1 to 2 degrees in an m-axis direction. A back surface (a surface opposite to the n-type layer 11) of the substrate 10 is a main surface for extracting light. An antireflection film may be provided on the back surface of the substrate 10 to improve light extraction efficiency. In addition, a surface of the substrate 10 may be provided with irregularities to improve the light extraction efficiency. As the substrate 10, an AlN substrate or an AlN template substrate in which an AlN layer is formed on a sapphire substrate may be used.

A thickness of the substrate 10 is, for example, 1000 μm or less. It is preferably 400 μm or more and 700 μm or less. Light extraction from a side surface of the substrate 10 can be prevented, and an axial intensity can be improved.

Note that, the substrate 10 may be removed by a method such as laser lift-off (LLO). In addition, an antireflection film may be provided on the back surface of the substrate 10 to improve the light extraction efficiency.

The n-type layer 11 is located on the substrate 10. The n-type layer 11 is made of n-AlGaN. An Al composition (a molar ratio of Al in all group III metals) is, for example, 60% to 90%. An n-type impurity is Si, and a Si concentration is, for example, 1×10¹⁸ cm⁻³ to 5×10¹⁹ cm⁻³. A thickness of the n-type layer 11 is, for example, 0.5 μm to 5 μm. A C concentration in the n-type layer 11 is 1×10¹⁵ cm⁻³ to 1×10¹⁹ cm⁻³. The n-type layer 11 may include a plurality of layers. In addition, a base layer made of AlN may be provided between the substrate 10 and the n-type layer 11. In addition, materials other than Si may be used as the n-type impurity.

The superlattice layer 12 is located on the n-type layer 11. The superlattice layer 12 is a layer having a structure in which AlGaN layers having different Al compositions are alternately stacked. When the superlattice layer 12 is provided, the strain in the active layer 14 can be relaxed.

The superlattice layer 12 has a two-layer structure in which, for example, a barrier layer made of Si-doped AlGaN and a well layer made of non-doped AlGaN are stacked in this order from an n-type layer 11 side. An Al composition in the barrier layer of the superlattice layer 12 is in a range similar to an Al composition in a barrier layer 140 of the active layer 14, or may be same as the above range. In addition, an Al composition in the well layer of the superlattice layer 12 is in a range similar to an Al composition in a well layer 141 of the active layer 14, or may be same as the above range. The barrier layer of the superlattice layer 12 has a thickness of 2 nm to 20 nm, and the well layer of the superlattice layer 12 has a thickness of 0.5 nm to 10 nm.

The hole blocking layer 13 is located on and in contact with the superlattice layer 12. The hole blocking layer 13 is made of AlGaN or AlN having an Al composition higher than that of the barrier layer 140 of the active layer 14. When the hole blocking layer 13 is provided directly below the active layer 14, the band of the entire active layer 14 can be flattened. Therefore, the light emitting recombination probability in the well layer 141 can be improved, and the light emission efficiency can be improved. In addition, holes injected from the p-side electrode 19 can be prevented from going beyond the active layer 14 and diffusing to the n-type layer 11 side.

A thickness of the hole blocking layer 13 is preferably one molecular layer to 2 nm. Within this range, the hole blocking layer 13 can fully exhibit a function thereof. In addition, electrons can be easily tunneled to an active layer 14 side, and efficiency of injecting electrons into the active layer 14 can be improved. Note that, in the case of AlN, one molecular layer is about 0.26 nm.

When the hole blocking layer 13 is made of AlGaN, the Al composition is preferably 80% or more.

The hole blocking layer 13 does not need to be in contact with the active layer 14, and a layer may be provided between the hole blocking layer 13 and the active layer 14. However, in order to improve the effect of flattening the band of the active layer 14, a distance between the hole blocking layer 13 and the active layer 14 is preferably 10 nm or less, and it is most preferable that the hole blocking layer 13 and the active layer 14 are in contact with each other.

The active layer 14 is located on the hole blocking layer 13. The active layer 14 has a quantum well structure (SQW) with one well layer, in which the barrier layer 140, the well layer 141, and an uppermost barrier layer 142 are stacked in this order from a hole blocking layer 13 side. The uppermost barrier layer 142 is a layer closest to the electron blocking layer 15, among the barrier layers in the active layer 14.

The barrier layer 140 has a structure in which a first barrier layer 140A and a second barrier layer 140B are stacked in this order from the hole blocking layer 13 side. The first barrier layer 140A is located on and in contact with the hole blocking layer 13. The second barrier layer 140B is located on and in contact with the first barrier layer 140A, and is in contact with a surface of the well layer 141 facing the n-type layer 11 side.

The first barrier layer 140A is made of AlGaN having an Al composition higher than that in the well layer 141, and the Al composition is, for example, 50% to 100%. The first barrier layer 140A is a non-doped layer. It may also be a lightly Si-doped layer, for example having a Si concentration of 1×10¹⁸ cm⁻³ or less. More preferably, it has a Si concentration of 1×10¹⁷ cm⁻³ or less, and still more preferably, it is non-doped. A thickness of the first barrier layer 140A is preferably 2 nm to 20 nm. When the Si concentration and the thickness are within the ranges, the Si concentration in the entire barrier layer 140 can be reduced while the function as a carrier barrier is sufficiently ensured.

The second barrier layer 140B is made of AlGaN having an Al composition higher than that in the well layer 141, and the Al composition is, for example, 50% to 100%. The Al composition in the second barrier layer 140B may be the same as the Al composition in the first barrier layer 140A. In addition, the second barrier layer 140B is a layer doped with Si at a concentration higher than that in the first barrier layer 140A. A Si concentration in the second barrier layer 140B is, for example, 1×10¹⁸ cm⁻³ to 2×10¹⁹ cm⁻³. A thickness of the second barrier layer 140B is, for example, 2 nm to 20 nm. When the Si concentration and the thickness are within the ranges, the effect of flattening the band of the active layer 14 can be sufficiently improved, and the Si concentration in the entire barrier layer 140 can be reduced.

An average Si concentration in the entire barrier layer 140 is preferably 0.5×10¹⁸ cm⁻³ to 1×10¹⁹ cm⁻³. An internal electric field between the p-type and n-type can be further reduced, and the deterioration in properties when a reverse bias is applied can be further reduced.

In the first embodiment, the Si concentration is changed in two stages, but it may be changed in three or more stages, or may be changed continuously. For example, a third barrier layer having a Si concentration intermediate between concentrations in the first barrier layer 140A and the second barrier layer 140B may be provided between the first barrier layer 140A and the second barrier layer 140B.

As described above, in the light emitting element 1 according to the first embodiment, the barrier layer 140 has a two-layer structure including the non-doped first barrier layer 140A and the Si-doped second barrier layer 140B. Therefore, the band of the active layer 14 can be flattened. As a result, the QCSE can be reduced and the light emitting recombination probability can be improved.

Since the first barrier layer 140A is non-doped, the Si concentration can be reduced compared to the case where the entire barrier layer 140 is doped with Si. Therefore, the internal electric field between the p-type and n-type can be reduced, and the deterioration in properties when a reverse bias is applied can be reduced in the light emitting element 1 according to the first embodiment. For example, it is possible to reduce a leakage current when a reverse bias is applied, to prevent a decrease in breakdown voltage, to prevent deterioration in ESD properties, and to improve reliability.

The well layer 141 is made of AlGaN, and an Al composition therein is set according to a desired emission wavelength. A Si concentration in the well layer 141 is, for example, 1×10¹⁸ cm⁻³ or less, and may be non-doped. A thickness of the well layer 141 is, for example, 0.5 nm to 5 nm.

The uppermost barrier layer 142 is the uppermost layer (a layer closest to the p-type contact layer 17) among the barrier layers in the active layer 14, and is in contact with the electron blocking layer 15. The uppermost barrier layer 142 is made of AlGaN having an Al composition higher than that in the well layer 141, and the Al composition is, for example, 50% to 100%. The Al composition in the uppermost barrier layer 142 may be the same as the Al composition in the first barrier layer 140A or the second barrier layer 140B. A thickness of the uppermost barrier layer 142 is preferably 0.5 nm to 10 nm. The uppermost barrier layer 142 may be either non-doped or Si-doped, and is preferably non-doped from the viewpoint of reducing the deterioration in properties when a reverse bias is applied.

Note that, the active layer is has an SQW structure in the first embodiment, or may be have an MQW structure including two or more well layers. In the case of the MQW structure, it is preferable that all of the barrier layers 140 other than the uppermost barrier layer 142, which is the uppermost layer among the barrier layers 140, have a two-layer structure including the first barrier layer 140A and the second barrier layer 140B as described above. In the case of the MQW structure, the uppermost barrier layer 142 is also preferably non-doped.

In the first embodiment, when the hole blocking layer 13 is provided directly below the active layer 14, the band of the entire active layer 14 can be flattened. Therefore, when the active layer 14 has an MQW structure, the efficiency of injecting holes into the well layer 141 on the n-type layer 11 side can be improved. Therefore, the number of well layers 141 having an MQW structure can be increased than a case in the conventional art. For example, in the conventional art, the number of well layers 141 was 1 to 3, but in the first embodiment, the number of well layers 141 can be 3 to 5.

The electron blocking layer 15 is located on the active layer 14. The electron blocking layer 15 has a two-layer structure in which a first electron blocking layer and a second electron blocking layer are stacked in this order from the active layer 14 side. The electron blocking layer 15 prevents electrons injected from the n-side electrode 18 from going beyond the active layer 14 and diffusing to a composition gradient layer 16 side.

Note that, the electron blocking layer 15 does not necessarily have a two-layer structure, and may include only the first electron blocking layer.

The first electron blocking layer is made of AlGaN or AlN having an Al composition higher than that in the barrier layer of the active layer 14, and the Al composition is, for example, 90% to 100%. In addition, the first electron blocking layer may be doped with a p-type impurity or may be non-doped. The p-type impurity is, for example, Mg. In the case of Mg-doped, a Mg concentration is, for example, 3×10²⁰ cm⁻³ or less. A thickness of the first electron blocking layer is, for example, 1 nm to 10 nm.

The second electron blocking layer is made of AlGaN having an Al composition lower than that in the first electron blocking layer, and the Al composition is, for example, 80% to 99%. When the second electron blocking layer is provided, a difference in Al composition from the composition gradient layer 16 is adjusted. A resistance is increased when the first electron blocking layer is made of only AlN, and when the first electron blocking layer is thinned, an electron blocking performance decreases. Therefore, the second electron blocking layer is provided to achieve both a low resistance and an electron blocking function. In addition, the second electron blocking layer may be doped with a p-type impurity or may be non-doped. In the case of Mg-doped, a Mg concentration is, for example, 3×10²⁰ cm⁻³ or less. A thickness of the second electron blocking layer is, for example, 1 nm to 10 nm.

The composition gradient layer 16 is located on the electron blocking layer 15. The composition gradient layer 16 has a two-layer structure in which a first composition gradient layer and a second composition gradient layer are stacked in this order from an electron blocking layer 15 side.

The composition gradient layer 16 is a p-type layer formed by a method called polarization doping. That is, the composition gradient layer 16 is a layer in which an Al composition changes in a thickness direction, and is set such that the Al composition is reduced as a distance from the electron blocking layer 15 increases. It is difficult to increase a hole concentration in AlGaN having a high Al composition when doped with Mg, but the hole concentration can be increased by polarization doping, and the efficiency of injecting holes into the active layer 14 can be improved. In addition, since the polarization doping does not require doping with Mg, crystallinity can be improved.

When the Al composition in the composition gradient layer 16 is set as described above, polarization due to a strain of crystals occurs continuously in the thickness direction in the composition gradient layer 16. Holes are generated in the composition gradient layer 16 so as to cancel out fixed charges due to the polarization. The generated holes are distributed in the composition gradient layer 16. Therefore, the holes are widely distributed in the thickness direction from the electron blocking layer 15 side in the composition gradient layer 16, and the entire composition gradient layer 16 becomes a p-type. In a p-type region, the hole concentration is 1×10¹⁶ cm⁻³ to 1×10²⁰ cm⁻³, and the hole concentration is reduced as the distance from the electron blocking layer 15 increases. A reason why the number of holes is reduced in the vicinity of an interface between the composition gradient layer 16 and the p-type contact layer 17 is that the band is bent as the Fermi levels try to match due to p-type heterojunction.

The first composition gradient layer is non-doped. Alternatively, it may be Mg-doped. A further increase in hole concentration due to a p-type impurity can be expected. In this case, the Mg concentration is, for example, 1×10²⁰ cm⁻³ or less.

The second composition gradient layer is a layer having a Mg concentration higher than that in the first composition gradient layer, and an Al composition in the second composition gradient layer is set to be similar to that in the first composition gradient layer. That is, the second composition gradient layer is a layer in which the Al composition changes in a thickness direction and is set such that the Al composition is reduced as the distance from the electron blocking layer 15 increases. The second composition gradient layer can be well connected to the p-type contact layer 17 by being doped with Mg.

Note that, the Al composition in the composition gradient layer 16 is continuously reduced in the first embodiment, or may be reduced stepwise. However, it is preferable that a region where the Al composition is constant is as small as possible.

The composition gradient layer 16 does not necessarily have a two-layer structure including the first composition gradient layer and the second composition gradient layer, and may include only the first composition gradient layer. In addition, the composition gradient layer 16 may have a structure of three or more layers having different change rates of the Al composition, different Mg concentrations, and the like.

Instead of the composition gradient layer 16, a layer made of Mg-doped p-type AlGaN may be provided. In this case, a Mg concentration is, for example, 1×10¹⁷ cm⁻³ to 1×10²⁰ cm⁻³. An Al composition is, for example, 40% to 80%.

The p-type contact layer 17 is located on the composition gradient layer 16. The p-type contact layer 17 is made of Mg-doped p-AlGaN. An Al composition therein may be smaller than the minimum Al composition in the composition gradient layer 16, and the Al composition is, for example, 60% or less. The p-type contact layer 17 may be made of p-GaN. A Mg concentration in the p-type contact layer 17 is, for example, 1×10²⁰ cm⁻³ to 1×10²² cm⁻³. A thickness of the p-type contact layer 17 is, for example, 1 nm to 200 nm.

The p-type contact layer 17 may include a plurality of layers having different Al compositions or Mg concentrations. In the case of a plurality of layers, an uppermost layer in contact with the p-side electrode 19 is preferably made of p-GaN or AlGaN having a low Al composition. This is to reduce a contact resistance with the p-side electrode 19. In this case, the Al composition in the AlGaN having a low Al composition is 50% or less.

A groove having a depth reaching the n-type layer 11 is provided in a partial region on a surface of the p-type contact layer 17. This groove is for exposing the n-type layer 11 so as to provide the n-side electrode 18 therein.

The n-side electrode 18 is provided on the n-type layer 11 exposed at a bottom surface of the groove. A material for the n-side electrode 18 is Ti/Al, V/Al, or the like. Here, A/B means that A and B are stacked in order from the n-type layer 11 side.

The p-side electrode 19 is provided on the p-type contact layer 17. The p-side electrode 19 is a reflective electrode that improves the light extraction efficiency by reflecting an ultraviolet ray emitted from the active layer 14 to a substrate 10 side. A material for the p-side electrode 19 is Ru, Rh, Ni/Au, Ni/Al, ITO/Al, or the like. Here, A/B means that A and B are stacked in order from a p-type contact layer 17 side. The p-side electrode 19 may be a combination of a transparent electrode such as ITO or IZO and a dielectric multilayer film (DBR).

As described above, in the light emitting element 1 according to the first embodiment, the barrier layer 140 of the active layer 14 has a stacked structure including the non-doped first barrier layer 140A and the Si-doped second barrier layer 140B. Since the second barrier layer is Si-doped, the band of the active layer 14 can be flattened and the light emitting recombination probability can be improved. In addition, since the non-doped first barrier layer 140A is provided, the Si concentration in the entire barrier layer 140 can be reduced, and the deterioration in properties when a reverse bias is applied can be reduced.

Next, various experiment results according to the first embodiment will be described.

### —Experiment 1—

For the light emitting element 1 according to the first embodiment, the hole blocking layer 13 and the active layer 14 were configured as follows (hereinafter, referred to as Example 1). Then, a band diagram and a carrier concentration of the light emitting element 1 in Example 1 were calculated by simulation.

A layer configuration of the hole blocking layer 13 and the active layer 14 in the light emitting element 1 in Example 1 is as follows, in order from the substrate 10 side.

Hole blocking layer 13: non-doped AlN, thickness: 0.5 nm

First barrier layer 140A: non-doped AlGaN (Al composition: 68%), thickness: 8 nm

Second barrier layer 140B: Si-doped AlGaN (Al composition: 68%, Si concentration: 3×10¹⁸ cm⁻³), thickness: 3 nm

Well layer 141: non-doped AlGaN (Al composition: 46%), thickness: 2 nm

Uppermost barrier layer 142: non-doped AlGaN (Al composition: 68%), thickness: 2 nm

A band diagram and a carrier concentration of a light emitting element (hereinafter, referred to as a light emitting element in Comparative Example) were similarly calculated, the Comparative Example being obtained by omitting the hole blocking layer 13 and replacing the two-layer structure including the first barrier layer 140A and the second barrier layer 140B with a single Si-doped AlGaN (Al composition: 68%, Si concentration: 3×10¹⁸ cm⁻³) layer having a thickness of 11 nm in the light emitting element 1 in Example 1.

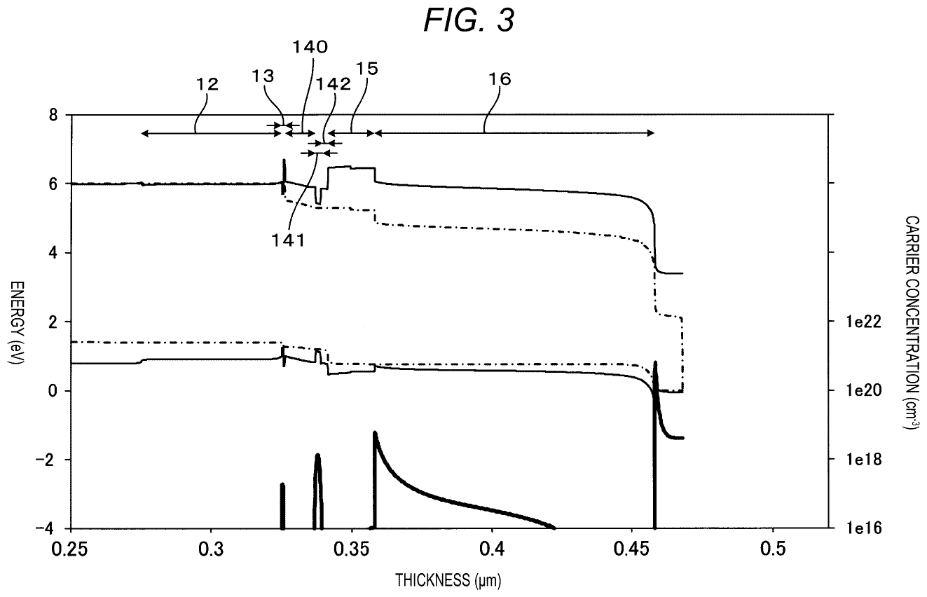

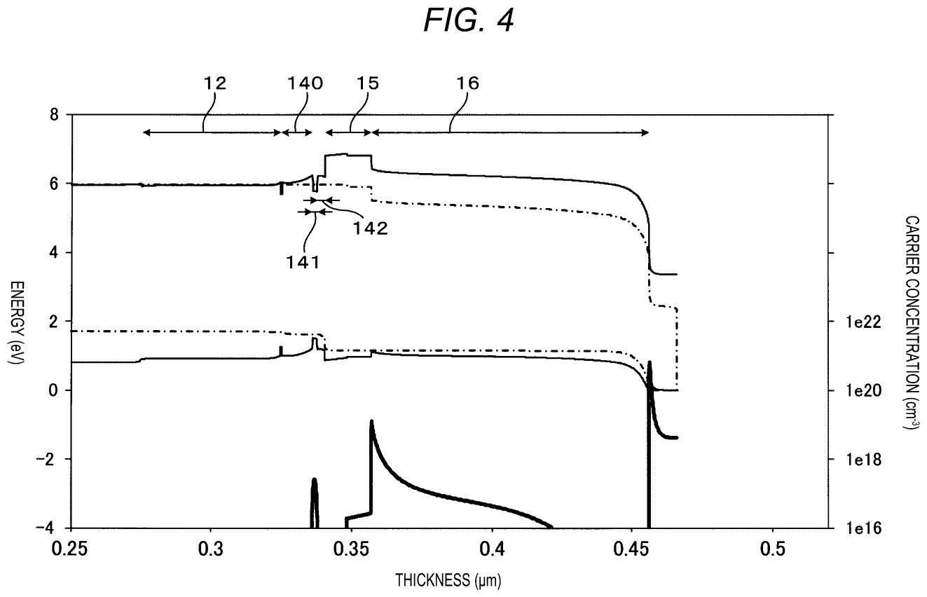

FIG. 3 shows the case where a voltage of 6 V is applied to the light emitting element 1 in Example 1. FIG. 4 shows the case where a voltage of 6 V is applied to the light emitting element in Comparative Example. In FIGS. 3 and 4, a thin line indicates the band diagram, and a thick line indicates the hole concentration.

As can be seen from FIG. 4, in the case of Comparative Example, the band of the barrier layer 140 has a slope upwards to the right. Therefore, holes are less likely to move to the n-side. In addition, holes are not well confined in the well layer 141.

On the other hand, as can be seen from FIG. 3, in the case of the light emitting element 1 in Example 1, the band of the barrier layer 140 is flatter than that in FIG. 4. In addition, the amount of holes injected into the well layer 141 increases. From this, it is thought that the flattening of the band makes it easier for holes to move to the n-side, and the amount of holes injected into the well layer 141 increases.

### —Experiment 2—

In the light emitting element 1 in Example 1, the active layer 14 was changed from SQW to MQW (hereinafter, referred to as a light emitting element 1 in Example 2). Then, a band diagram and a carrier concentration of the light emitting element 1 in Example 2 were calculated by simulation.

A layer configuration of the hole blocking layer 13 and the active layer 14 in the light emitting element 1 in Example 2 is as follows, in order from the substrate 10 side, and the active layer 14 has two MQW well layers 141.

Hole blocking layer 13: non-doped AlN, thickness: 0.5 nm

First barrier layer 140A: non-doped AlGaN (Al composition: 68%), thickness: 8 nm

Second barrier layer 140B: Si-doped AlGaN (Al composition: 68%, Si concentration: 3×10¹⁸ cm⁻³), thickness: 3 nm

Well layer 141: non-doped AlGaN (Al composition: 46%), thickness: 2 nm

First barrier layer 140A: non-doped AlGaN (Al composition: 68%), thickness: 8 nm

Second barrier layer 140B: Si-doped AlGaN (Al composition: 68%, Si concentration: 3×10¹⁸ cm⁻³), thickness: 3 nm

Well layer 141: non-doped AlGaN (Al composition: 46%), thickness: 2 nm

Uppermost barrier layer 142: non-doped AlGaN (Al composition: 68%), thickness: 2 nm

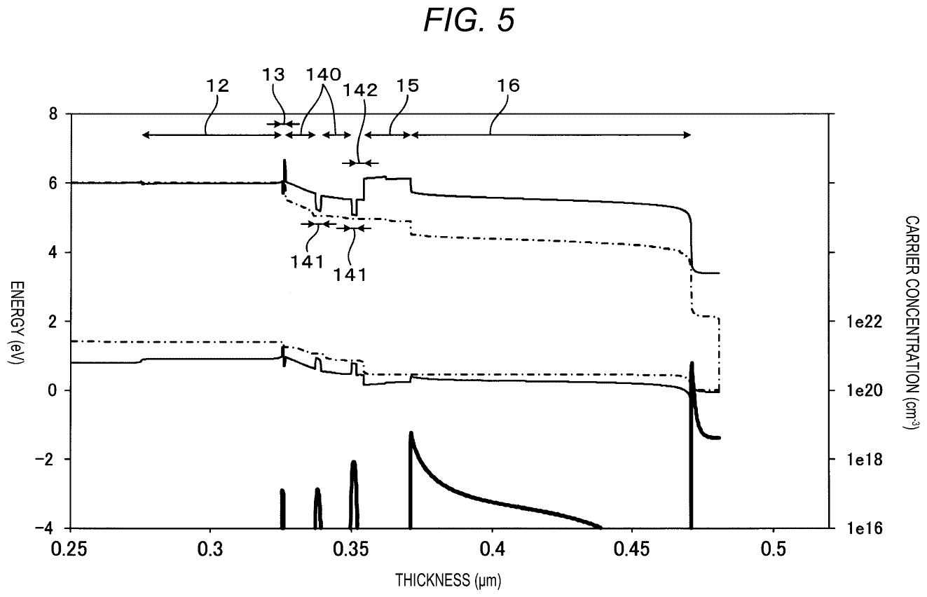

As can be seen from FIG. 5, in the case of the light emitting element 1 in Example 2, the band of the barrier layer 140 is flatter than that in FIG. 4. In addition, the amount of holes injected into the well layer 141 increases. In particular, holes are also efficiently injected into the well layer 141 on the hole blocking layer 13 side, among the two well layers 141.

### REFERENCE SIGNS LIST

1: light emitting element
10: substrate
11: n-type layer
12: superlattice layer
13: hole blocking layer
14: active layer
15: electron blocking layer
16: composition gradient layer
17: p-type contact layer
18: n-side electrode
19: p-side electrode
140: barrier layer
141: well layer
142: uppermost barrier layer

What is claimed is:

1. A light emitting element that emits an ultraviolet ray, the light emitting element comprising:
an n-type layer comprising an n-type group III nitride semiconductor containing Al;
an active layer located over the n-type layer, comprising a group III nitride semiconductor containing Al, and having a quantum well structure including a well layer and a barrier layer; and
a p-type layer located over the active layer and comprising a p-type group III nitride semiconductor containing Al, wherein
the barrier layer comprises
a first barrier layer non-doped or doped with an n-type impurity, and
a second barrier layer located over the first barrier layer, being in contact with a surface of the well layer at a side of the n-type layer, and doped with an n-type impurity at a concentration higher than a concentration of the n-type impurity doped in the first barrier layer.

2. The light emitting element according to claim 1, wherein an uppermost barrier layer, which is a layer closest to the p-type layer among layers included in the barrier layer, is a non-doped group III nitride semiconductor.

3. The light emitting element according to claim 1, wherein the first barrier layer is non-doped, and the second barrier layer has a Si concentration of 1×10¹⁸ cm⁻³ to 2×10¹⁹ cm⁻³.

4. The light emitting element according to claim 2, wherein the first barrier layer is non-doped, and the second barrier layer has a Si concentration of 1×10¹⁸ cm⁻³ to 2×10¹⁹ cm⁻³.

5. The light emitting element according to claim 1, wherein the first barrier layer has a thickness of 2 nm to 20 nm, and the second barrier layer has a thickness of 2 nm to 20 nm.

6. The light emitting element according to claim 2, wherein the first barrier layer has a thickness of 2 nm to 20 nm, and the second barrier layer has a thickness of 2 nm to 20 nm.

7. The light emitting element according to claim 1, further comprising:
a hole blocking layer located between the n-type layer and the active layer so that the hole blocking layer is in contact with the active layer, and comprising AlGaN or AlN having an Al composition higher than an Al composition in the barrier layer.

8. The light emitting element according to claim 2, further comprising:
a hole blocking layer located between the n-type layer and the active layer so that the hole blocking layer is in contact with the active layer, and comprising AlGaN or AlN having an Al composition higher than an Al composition in the barrier layer.

9. The light emitting element according to claim 7, further comprising:
a superlattice layer located between the n-type layer and the hole blocking layer so that the superlattice layer is in contact with the hole blocking layer, and formed by alternately stacking group III nitride semiconductors having different Al compositions.

10. The light emitting element according to claim 8, further comprising:
a superlattice layer located between the n-type layer and the hole blocking layer so that the superlattice layer is in contact with the hole blocking layer, and formed by alternately stacking group III nitride semiconductors having different Al compositions.

11. The light emitting element according to claim 7, wherein the active layer has an MQW structure.

12. The light emitting element according to claim 8, wherein the active layer has an MQW structure.
